(19) United States
(12) Patent Application Publication
(10) Pub. No.: US 2016/0313282 A1
(43) Pub. Date: Oct. 27, 2016

(54) MOTFT AND ARRAY CIRCUIT FOR CHEMICAL/BIOCHEMICAL APPLICATIONS

(71) Applicants: Chan-Long Shieh, Paradise Valley, AZ (US); Gang Yu, Santa Barbara, CA (US); Donald E. Ackley, Cardiff, CA (US)

(72) Inventors: Chan-Long Shieh, Paradise Valley, AZ (US); Gang Yu, Santa Barbara, CA (US); Donald E. Ackley, Cardiff, CA (US)

(21) Appl. No.: 15/139,134

(22) Filed: Apr. 26, 2016

Related U.S. Application Data
(60) Provisional application No. 62/153,507, filed on Apr. 27, 2015.

(51) Int. Cl. G01N 27/447; H01L 29/786; H01L 29/43

(52) U.S. Cl. CPC G01N 27/44782; H01L 29/43; H01L 29/7869; G01N 27/44717

(57) ABSTRACT

Electro-chemical manipulation and charge sensing apparatus includes a chemical/biochemical testing pad positioned on a dielectric substrate, a sensing circuit coupled to the testing pad, the sensing circuit including at least one MOTFT device, and a manipulation and control circuit coupled to the testing pad, the manipulation and control circuit including at least one MOTFT device. The electro-chemical manipulation and charge sensing apparatus can include a plurality of chemical/biochemical testing pads distributed in a matrix formation of rows and columns and positioned on a dielectric substrate.

### CROSS-REFERENCE TO RELATED APPLICATIONS

This application claims the benefit of U.S. Provisional Patent Application No. 62/153,507, filed 27 Apr. 2015.

### FIELD OF THE INVENTION

This invention generally relates to MOTFT sensor arrays for use in Chemical/Biochemical applications.

### BACKGROUND OF THE INVENTION

The electrical manipulation of biochemical reactions/bindings and the subsequent electrical detection of bio-chemical events are powerful tools in biotechnology. Array devices with multiple cells/channels improve detection sensitivity and reliability. They also enable testing multiple reaction events at different cells by means of combinatorial chemistry and improving screening/analysis throughput significantly.

The first wave of technology development was to implement this in Si-wafer based technology. Test sensors and circuits made with Si technology have high performance, but the cost per unit area is too high to be used for many disposable biochemical applications. Additionally, there are some disadvantages for Si in terms of charge detection. The Si technology has a conductive substrate (crystalline silicon) and therefore it is difficult to reduce the parasitic capacitance to enhance the sensitivity of charge detection. Moreover, the wafer substrate is not transparent to visible and UV light and cannot take advantages of self-aligning techniques in fabricating such structures as interdigitated electrodes.

With transparent glass or plastic substrates (i.e. dielectric or insulating substrates), one can minimize the parasitic capacitance of interconnection lines and improve the sensitivity of the charge detection. Amorphous-Si thin film transistors (a-Si TFT), low-temperature polysilicon thin film transistors (LTPS-TFT) or metal-oxide thin film transistors (MOTFT) can be fabricated on glass or plastic substrates. A-Si TFTs have a mobility less than 1 cm²/Vs and cannot be used for applications where high pixel “ON” current and low resistance are required. For electrical control of charged and dielectric species by means of electrophoresis and/or dielectrophoresis, and/or for biochemical/chemical reactions (such as reduction and oxidation, redox), a substantial amount of current may be needed for the pixel driver. A current density as high as 10 A/cm² may be needed for each test pad. On a single electrode, the required current can be as high as several mA. This places a big burden on the control transistor which cannot be achieved by a-Si TFT. On the other hand, although a poly-silicon based TFT can provide the “ON” current, it is hard to shut off to a level that charge leakage becomes negligible during the charge sensing period. A TFT with high “ON” current and low “OFF” current and with current switch ratio beyond 10 orders of magnitudes is needed for such application.

CBRITE has developed a series of metal-oxide thin film transistors (MOTFTs) on glass or plastic substrates (for examples, U.S. Pat. No. 7,812,346; U.S. Ser. No. 12/206,615; U.S. Pat. No. 8,907,336; U.S. Ser. No. 14/552,641; U.S. Pat. No. 7,977,151; U.S. Pat. No. 8,129,720; U.S. Pat. No. 8,273,600; U.S. Pat. No. 8,679,905; U.S. Ser. No. 14,175,521; U.S. Ser. No. 13/718,183; U.S. Ser. No. 13/536,641; U.S. Ser. No. 13/902,514; U.S. Ser. No. 14/081,130). High electron mobility was achieved in a range of 10-100 cm²/Vsec (Gang Yu et al., SID Symposium Digest, Vol. 42, p. 483 (2011); G. Yu et al., SID Symposium Digest, Vol. 43, p. 1123 (2012)) by proper channel material selection and proper TFT design. “ON” current in a range of 1-100 mA can be achieved by proper TFT geometric designs. Thus, microreactor/sensor arrays made with high mobility and high switch ratio MOTFTs are disclosed and incorporated in the present invention.

It would be highly advantageous, therefore, to remedy the foregoing and other deficiencies inherent in the prior art.

Accordingly, it is an object of the present invention to provide new and improved electro-chemical manipulation and charge sensing apparatus.

It is another object of the present invention to provide new and improved electro-chemical manipulation and charge sensing apparatus coupled to a common electrode in a testing cell.

It is another object of the present invention to provide new and improved electro-chemical manipulation and charge sensing apparatus incorporating MOTFT devices.

It is another object of the present invention to provide new and improved electro-chemical manipulation and charge sensing apparatus incorporating MOTFT devices fabricated in matrix form.

It is another object of the present invention to provide new and improved electro-chemical manipulation and charge sensing apparatus incorporating MOTFT devices fabricated in an active matrix form.

It is another object of the present invention to provide new and improved electro-chemical manipulation and charge sensing apparatus incorporating MOTFT devices fabricated in an active matrix form with row or individually addressable dielectrophoresis (DEP) electrodes.

### SUMMARY OF THE INVENTION

The desired objects of the instant invention are achieved in accordance with an embodiment of an electro-chemical manipulation and charge sensing apparatus including a chemical/biochemical testing pad positioned on a dielectric substrate, a sensing circuit coupled to the testing pad, the sensing circuit including at least one MOTFT device, and a manipulation and control circuit coupled to the testing pad, the manipulation and control circuit including at least one MOTFT device. The electro-chemical manipulation and charge sensing apparatus can include a plurality of chemical/biochemical testing pads distributed in a matrix formation of rows and columns and positioned on a dielectric substrate.

The desired objects of the instant invention are also achieved in accordance with a specific embodiment thereof wherein electro-chemical manipulation and charge sensing apparatus includes a chemical/biochemical testing pad positioned on a dielectric substrate. The testing pad is designed for dielectrophoresis (DEP) testing and includes a dielectrophoresis electrode and an ion selective/sensitive electrode positioned in charge sensing proximity to the dielectrophoresis electrode. A sensing MOTFT circuit is positioned on the ion selective/sensitive electrode, the sensing circuit including a bottom gate MOTFT device with the gate positioned in contact with the ion selective/sensitive electrode.

The desired objects of the instant invention are also achieved in accordance with a specific embodiment thereof wherein electro-chemical manipulation and charge sensing apparatus includes a plurality of chemical/biochemical testing pads distributed in a matrix formation of rows and columns and positioned on a dielectric substrate. Each chemical/biochemical testing pad is designed for dielectrophoresis (DEP) testing and includes a dielectrophoresis electrode and an ion selective/sensitive electrode positioned in charge sensing proximity to the dielectrophoresis electrode. Each chemical/biochemical testing pad includes a sensing MOTFT circuit positioned on the ion selective/sensitive electrode.

### BRIEF DESCRIPTION OF THE DRAWINGS

The foregoing and further and more specific objects and advantages of the instant invention will become readily apparent to those skilled in the art from the following detailed description of a preferred embodiment thereof taken in conjunction with the drawings, in which:

FIG. 1a is a simplified circuit diagram illustrating a single electrode connected to perform both electro-chemical manipulation and charge sensing in accordance with the present invention;

FIG. 1b is a simplified block diagram of a circuit similar to that illustrated in FIG. 1a, wherein the blocks may include multiple MOTFTs;

FIG. 2 is a simplified circuit diagram illustrating the single electrode of FIG. 1a including interdigitated manipulation electrodes in accordance with the present invention;

FIG. 3 is a simplified circuit diagram illustrating the interdigitated manipulation electrodes of FIG. 2 fabricated by a self-aligned process in accordance with the present invention;

FIG. 4a is a graphical representation of the Id-Vgs curve for a MOTFT with a gate of width (W) equal to 5 μm and a length (L) equal to 8 μm;

FIG. 4b is a graphical representation of the Id-Vgs curve for a MOTFT with a gate of width (W) equal to 10,000 μm and a length (L) equal to 6 μ

FIG. 5 illustrates a specific example of a dielectrophoresis and sensing device in accordance with the present invention;

FIG. 6 illustrates an example of a dielectrophoresis and sensing device with charge amplification in accordance with the present invention;

FIG. 7 is a schematic diagram of the dielectrophoresis and sensing device of FIG. 5 connected in an individually addressable configuration;

FIG. 8 illustrates the individually addressable dielectrophoresis and sensing device of FIG. 6 incorporated into a sensing array in accordance with the present invention;

FIG. 9 illustrates specific individually addressable dielectrophoresis and sensing devices incorporated into a sensing array in accordance with the present invention;

FIG. 10 illustrates schematically the specific individually addressable dielectrophoresis and sensing devices incorporated into the sensing array of FIG. 9; and

FIG. 11 illustrates specific construction in MOTFTs of the specific individually addressable dielectrophoresis and sensing devices of FIG. 10.

### DETAILED DESCRIPTION OF THE DRAWINGS

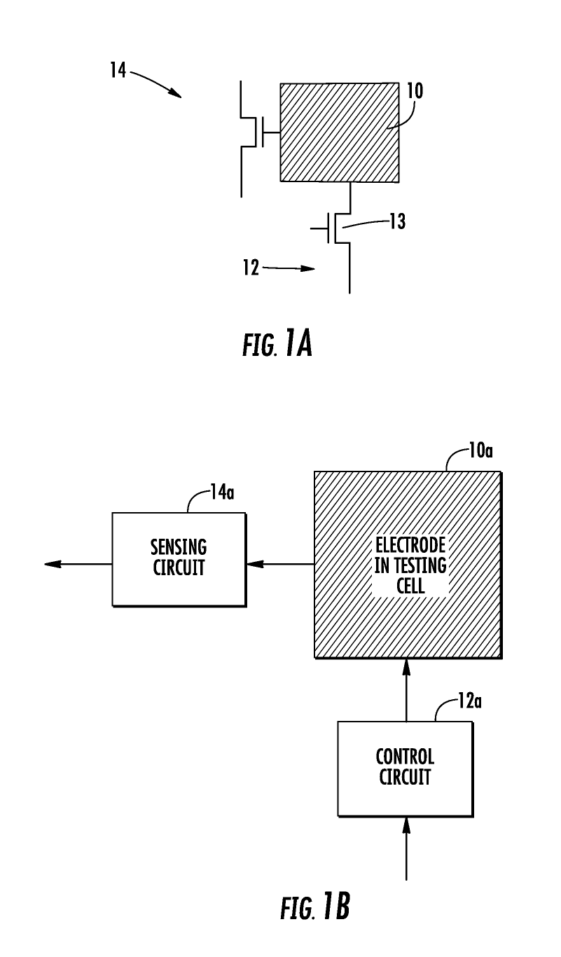

The screening/analysis technology can be implemented as shown in the general diagram in FIG. 1a where a single metal pad or electrode 10 is used to do both the electro-chemical manipulation and the charge sensing. In the following description, the term “manipulation” is used generally for all types of physical motions, particle separation and chemical reaction processes. During the charge sensing phase, electrode 10 has to be isolated from control electronics 12 to enable a sensing TFT 14. The best way to provide the “manipulation” function to sensing electrode 10 is to include a control switch transistor 13 between electrode 10 and the driver electronics in a peripheral area of the sensor array (not shown). Transistor 13 is switched OFF during the charge sensing phase and is turned on during the control/manipulation phase where large current, or high biasing voltage may pass through. In certain applications such as electrophoresis/dielectrophoresis or redox reactions, the current switching requirement on control transistor 13 is very demanding. The on current may be on the order of mA and the OFF current should be on the order of fA or sub-fA (when sensitivity<10³ electrons/sec is needed). For such radical current swings control transistor 13 requires a current switch ratio (Iₒₙ/I_{off}) of >1E12 (10¹²). Neither a-Si TFTs, nor poly-silicon TFTs have shown the capability to handle such large current switch ratios. Also, it is very challenging for Si wafer based transistors to meet this requirement.

The example in FIG. 1a illustrates constructing a sensing circuit and a control circuit each with a single MOTFT for the screening/analysis technology. However, sensing and control circuits can also be constructed with multiple MOTFTs with additional functions (as shown/implied generically in the block diagram of FIG. 1b). For example, in combination with an electrode 10a, charge amplification, reset, dynamic range control, oversampling, analog-to-digital conversion can be added in a sensing circuit 14a and/or pulsed or continuous wave signals can be achieved with proper designs of a control circuit 12a.

Another approach is to incorporate separate electrodes for the control/manipulation and the sensing functions. Since the biochemical events are enhanced by the manipulation electrode, any charge redistribution must occur in the manipulation electrode neighborhood. To take advantage of this fact, sensing electrodes 20 are interdigitated to manipulation electrode 22, as shown in FIG. 2. The closeness of sensing digits or fingers 24 of interdigitated sensing electrode 20 to each other and to digits or fingers 26 of manipulation electrode 22 is constrained by any lithography processes for forming the digits or fingers of the interdigitated electrodes 20 and 22. A better lithography tool will enable close charge coupling between the two sets of electrodes 20 and 22. However, lithography tools with sub-micron gap process control are all expensive and processing over a large area is also time consuming and costly. Therefore, the present invention utilizes a self-aligned process to build the interdigitated electrodes of electrodes 20 and 22 without resorting to expensive lithography tools, such as ebeam and the like.

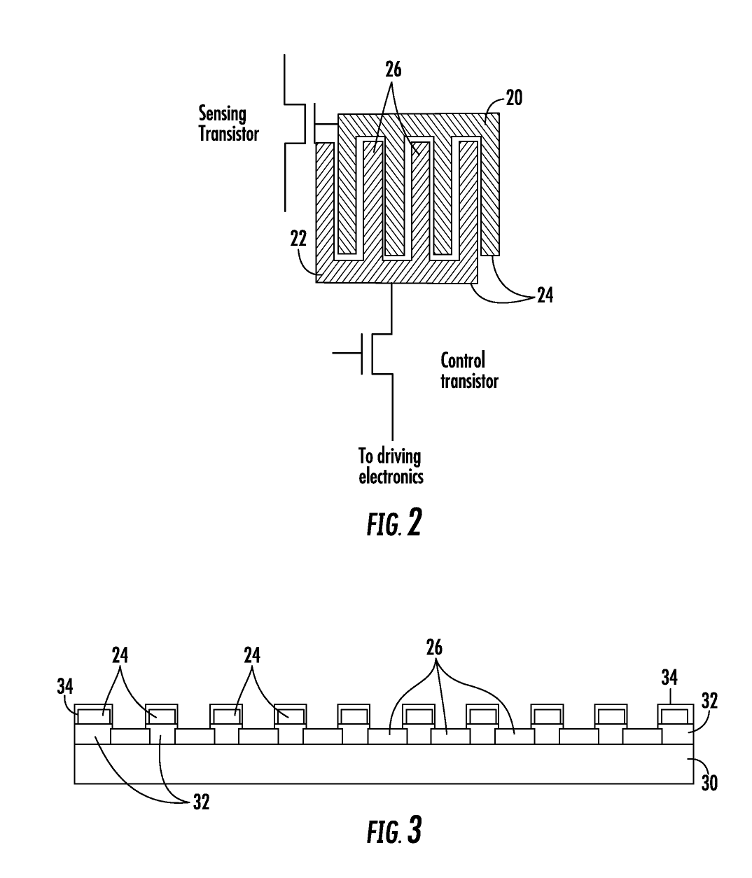

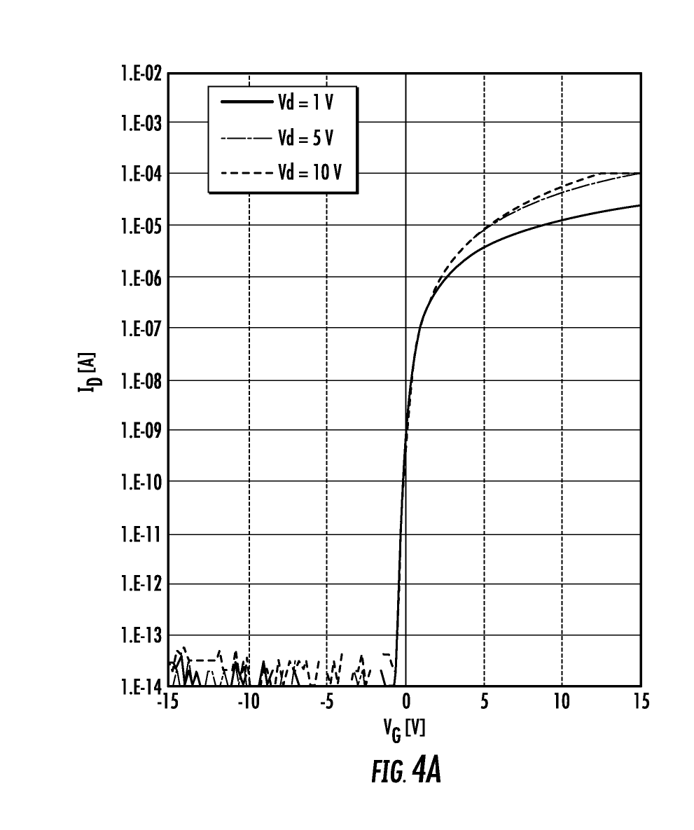

Referring specifically to FIG. 3, a self-aligned process for fabricating the interdigitated electrodes of FIG. 2 is illustrated. As shown in FIG. 3, an opaque electrode is deposited and patterned into opaque digits or fingers 26 of manipulation electrode 22 on a transparent substrate 30 (in this specific example glass) using conventional lithography tools. The width and space of the line can be achieved up to the design rule of the given lithography tool utilized.

A first transparent insulation layer is deposited so as to form separation pedestals 32 between opaque digits or fingers 26. The first insulation layer can be formed into separation pedestals 32 by several different processes, including for example blanket deposition, negative photo resist, self-aligned exposure and etching or selective deposition.

A transparent conductor layer (e.g. ITO or the like) is then deposited over the first insulator layer as the sensing electrode layer 20. A negative resist layer is coated over the transparent conductor layer and exposed by back side illumination (with the opaque electrodes 26 providing a built-in mask). After development of the negative resist layer, the transparent conductor layer is etched, using the negative resist as the mask, to form sensing digits 24. Sensing digits 24 are perfectly aligned with opaque digits or fingers 26 and separated by a difference in height or depth between higher separation pedestals 32 and lower opaque electrodes 26 (as illustrated in FIG. 3).

Another insulation layer is deposited over transparent electrodes 24 to protect transparent electrodes 24 from the test solution. A positive resist layer is then coated and exposed through the back (substrate 30). After development, the resist on top of the first opaque metal is developed away but insulation layer 34 remains on transparent electrodes 24. The insulation layer on top of opaque electrodes 26 can then be etched away using this resist so that opaque electrodes 26 will be exposed to test solutions. The remaining positive photoresist and insulation layer 34 underneath (illustrated as a common or single layer in FIG. 3) can be used as the wall of a test cell to retain solutions on the test cell.

It should be noted that, in addition to or instead of the parallel layout shown in FIG. 2, interdigitated control/sensing electrodes 26 and 24 can be arranged in other shapes for special interests. For example, interdigitated control/sensing electrodes 26 and 24 can be arranged—in a radial shape to form a circuit pixel electrode (examples of constructing MOTFT with source/drain electrodes self-aligned to its gate electrode have been disclosed in U.S. Pat. No. 7,605,026; U.S. Pat. No. 7,977,151; U.S. Pat. No. 8,129,720). Further, the two configurations in FIGS. 1 and 2 only illustrate a unit cell but arrays comprising multiple unit cells can be individually addressed similar to the pixels in a display by properly wiring to each unit, or by incorporating an active matrix to address each pixel/cell at each inter-section point of the x-y matrix.

The performance of the MOTFT disclosed in this invention is capable of performing all circuit and unit requirements for the pixel/cell. It should also be noted that the performance of such MOTFT is also capable of performing functions for the peripheral driving circuits including shift register, level shifter, multiplexer and demultiplexer, etc. Thus, the examples disclosed provide or perform a low cost, disposable microreactor/sensor array with high performance metal-oxide thin film transistors. As is known in the biochemical/chemical sensor field, pH sensing is a special case for charge sensing based on the same principle.

In contrast to sensors fabricated on silicon wafers wherein the silicon wafer substrate is a semiconductor with energy gap close to 1 eV, the MOTFTs described herein and the circuits built with such devices can be made on insulating glass or plastic substrates with an energy gap typically in 4-10 eV range. The energy gap of the channel metal oxide in the MOTFTs is typically larger than 3.1 eV. These high energy gap dielectric and semiconductor materials enable such MOTFT switches to turn off with negligible leakage current.

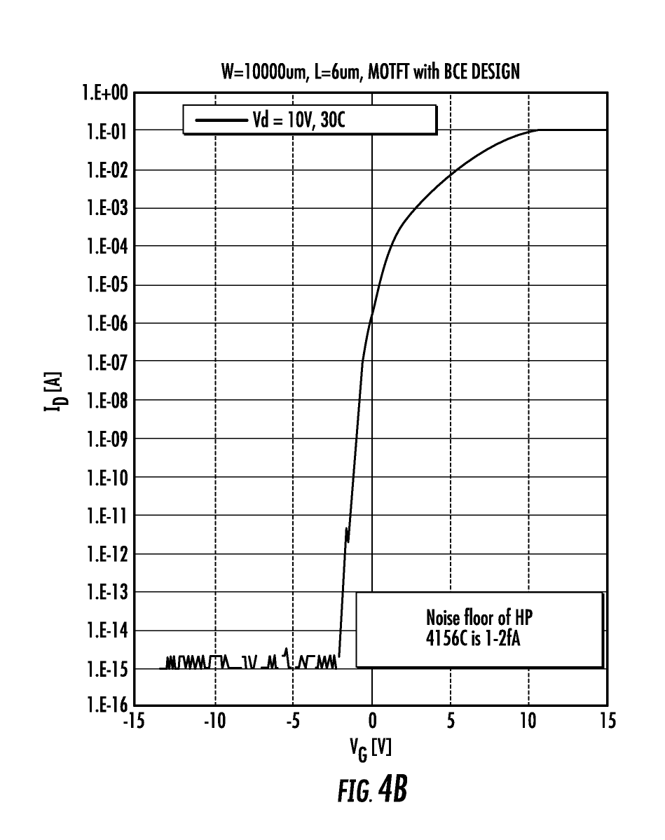

Referring specifically to FIGS. 4a and 4b, the Id-Vgs characteristics of two different MOTFTs are illustrated. FIG. 4a is a MOTFT with channel width (W) and channel length (L) equal to 5 um and 8 um respectively. The I_{off} is ˜10⁻¹⁴ A which is limited by the testing system (HP/Agilent 5156C). To explore the real I_{off}, a MOTFT with large area, W/L=10,000 um/6 um, was tested. The result is shown in FIG. 4b. Short channel effect was not seen. The OFF current was confirmed at 10⁻¹⁵ A, independent of Vds bias. The tested number of 1-2 fA was still limited by the noise floor of the Agilent test setup, so that this number provides only an upper limit. For a W=10 um, L=5 um control transistor, the OFF current will be ˜10⁻¹⁸ A. Noticing 1 A=1 Coulomb/sec, and 1 electron=1.6×10⁻¹⁹ Coulomb/Sec, the leakage current of a control transistor with W=5 um and L=5 um, thus, only leaks less than 10 electrons during 1 second “OFF” period. The ON current is −100 mA at 10V. For a MOTFT with W/L˜20 (e.g., W=100 um and L=5 um), more than 1 mA can be reached at Vgs=10V. Such a MOTFT is thus ideal to be used for the control circuit of a biochemical/chemical microreactor/sensor and sensor array. The switch behavior and the ON current of the MOTFT is nearly independent of temperature in a range of 20-100° C. Such a MOTFT enables the fabrication of simple control circuits without temperature compensation. These MOTFTs are also stable under high voltage and current bias (Gang Yu et al., SID Symposium Digest, Vol. 42, p. 483 (2011); G. Yu et al., SID Symposium Digest, Vol. 43, p. 1123 (2012)). The biochemical/chemical microreactor/sensor array can thus be used for bio-amplification reaction with multiple cycles.

It should be noted that the microreactor/sensor cell over the electrode has an open top surface and, therefore, light illumination can be achieved from top. When light illumination from bottom of the cell is desired, a transparent electrode (such as conductive SnO film, or semitransparent Au, Ni, Cr, Mo, or Pt film) can be used for the cell electrode.

Physical manipulation or various chemical/biochemical reactions can thus be achieved with the microreactor/sensor with pixel circuit described in conjunction with FIG. 1 above, including chemical reaction, electrochemical reaction (such as redox), photochemical and photoelectrochemical reactions.

Turning to FIG. 5, a specific example of a dielectrophoresis and sensing device 40 for use in control and sensing circuits, such as shown in FIG. 1b, is illustrated in accordance with the present invention. As understood in the art, dielectrophoresis (DEP) is a technique for separating cells and nucleic acids from blood using AC fields. In a typical application, circular electrodes are fabricated as arrays of dots which are all interconnected. Often, for stability in biological fluids the electrodes are fabricated from TiPt (titanium-platinum) and isolated with SiNₓ. In order to improve the functionality of these separation arrays, an individually addressable array of charge sensors, typically comprising ion selective/sensitive FETs (ISFETs) may be added on top of the DEP electrode array. In this specific example the ISFETs are preferentially fabricated as thin film transistors (TFTs) using a metal oxide as the channel material (MOTFTs).

In the specific example illustrated in FIG. 5, an ISFET electrode 42 is connected to a bottom gate MOTFT 44. In this simplified example, ISFET electrode 42 is deposited on a layer 45 of SiNₓ which is deposited on an insulating substrate 41 (in this specific example glass). Subsequently, a TiPt DEP electrode 43 is deposited on substrate 41 first and layer 45 of SiNₓ is formed over electrode 43 so as to define a solution “dish” 43a over electrode 43. A gate 46 is deposited on ISFET electrode 42, an active layer 47 of metal oxide is deposited on gate 46, and source/drain electrodes 48 are formed on active layer 47 so as to define a channel area between the spaced apart source/drain electrodes 48. ISFET electrode 42 forms a centrally located disk with TiPt DEP electrode 43 forming a concentric ring around ISFET electrode 42 and spaced therefrom by the depth of dish 43a.

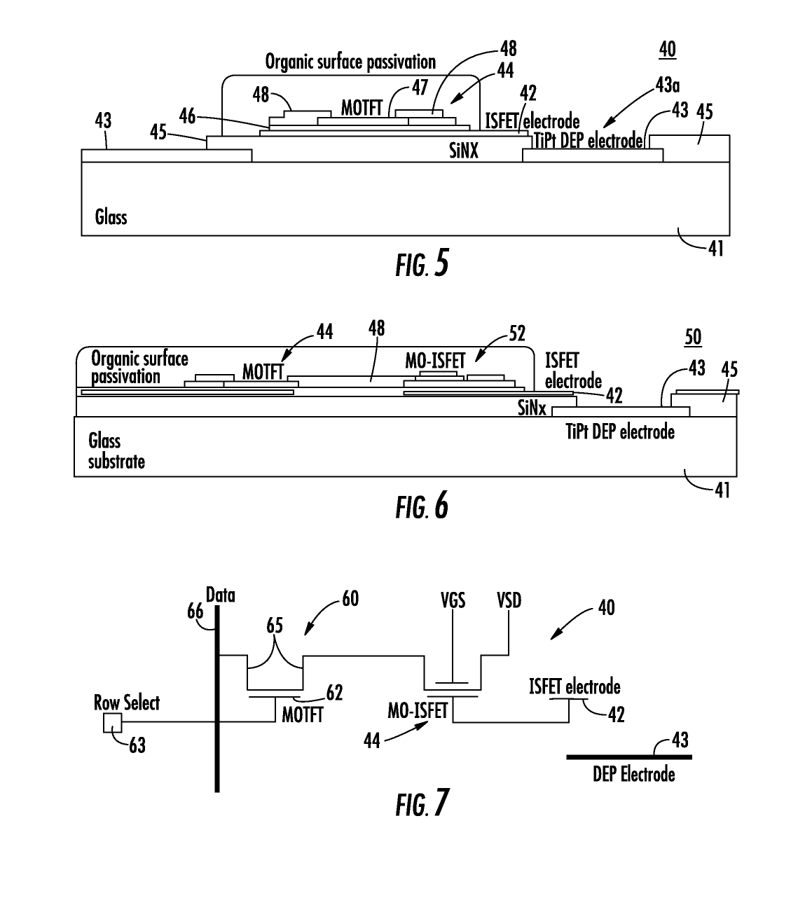

An example of a dielectrophoresis and sensing device 50 with charge amplification is illustrated in FIG. 6. In device 50 a dual-gate MOTFT 52 is positioned between the bottom gate MOTFT 44 and the outer (or sensing edge of ISFET electrode 42) to provide charge amplification. The top gate of the dual-gate MOTFT 52 is connected to its drain electrode (or another potential provided externally), and the bottom gate of the dual-gate MOTFT 52 is connected to the sensing electrode 42. Maintaining a constant current on the dual-gate MOTFT provides a charge amplification effect at the two gate electrodes. The amplification is the ratio of the bottom gate capacitance to the top gate capacitance because the charges induced by both gates cancel each other. When different dielectric materials and thicknesses are selected for the dielectric layers above and below the channel layer, a desire amplification factor can be achieved.

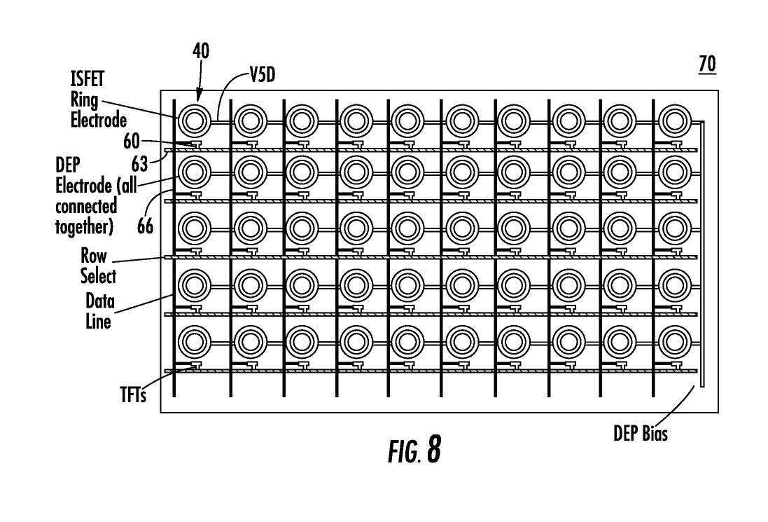

Turning now to FIG. 7, a schematic diagram of the dielectrophoresis and sensing device 40 of FIG. 5 connected in an individually addressable configuration is illustrated. In order to optimize the sensor performance of dielectrophoresis and sensing device 40 when incorporated in a sensing array, each device 40 is individually addressable in an active matrix format. In the example illustrated in FIG. 7 additional switching MOTFT 60 is provided, similar to the switching MOTFT 44 shown in FIG. 6. MOTFT 60 includes a gate 62 connected to a row select pad 63 and source/drain terminals 65 connected to a data line 66. Thus, in a manner well known in the active matrix art, a signal on data line 66 at the same time as a signal on row select pad 63 activates MOTFT 60 to cause sensing device 40 to provide an output signal at an output terminal VSD. As explained previously, MOTFT 60 is very well suited for this function since it provides very low OFF current and low channel resistance when switched on.

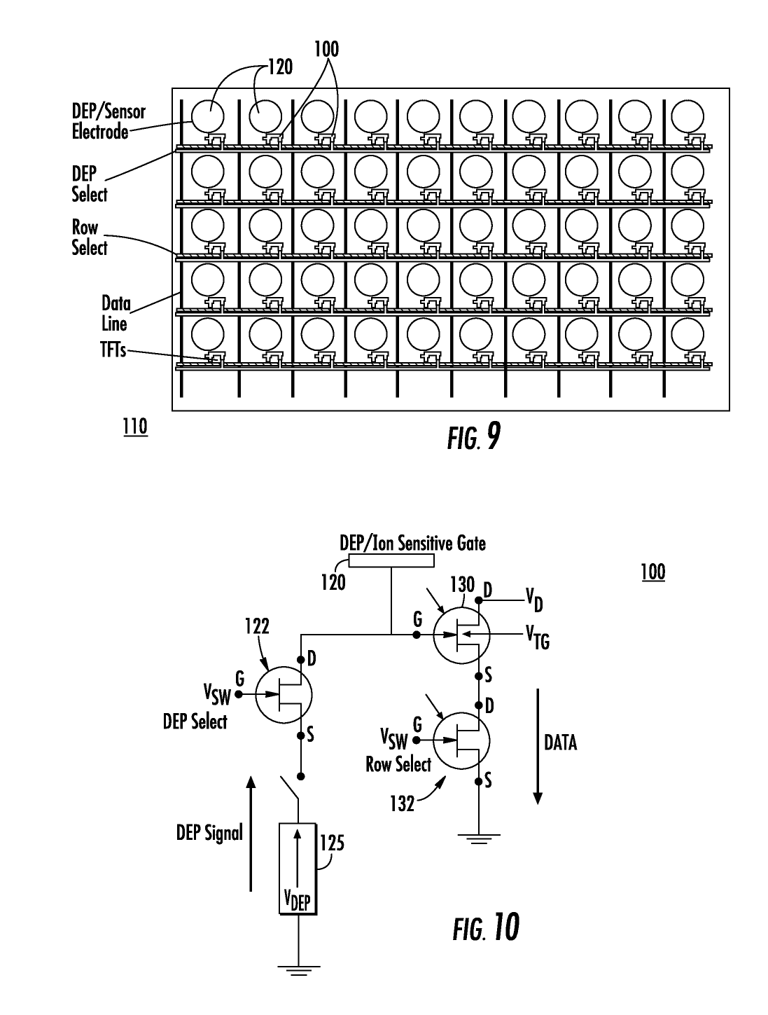

Referring additionally to FIG. 8, an example of a plurality of dielectrophoresis and sensing devices 40 incorporated in a sensing array 70 is illustrated. The V_{SD} output of each dielectrophoresis and sensing devices 40 is connected to the next data line in sensing array 70. As explained above, each dielectrophoresis and sensing device 40 is individually addressable by selecting a data line 66 and a row 63 to activate the associated MOTFT 60. It will be understood that when a single solution to be tested is applied to the entire sensing array 70, instead of selecting a single dielectrophoresis and sensing devices 40, a complete row of devices might be sensed simultaneously to increase the output signal to a more useable amplitude. In FIG. 8, for example, MOTFTs 60 allow rows of dielectrophoresis and sensing devices 40 to be selected from sensing array 70, and the sensor data is then read out through the next column data line. Array design with shared buslines for both driving data and V_{SD} enable high pixel density. In certain circumstance pixel density is less demanding, separate data lines and VSD lines may be used for more driving and readout options.

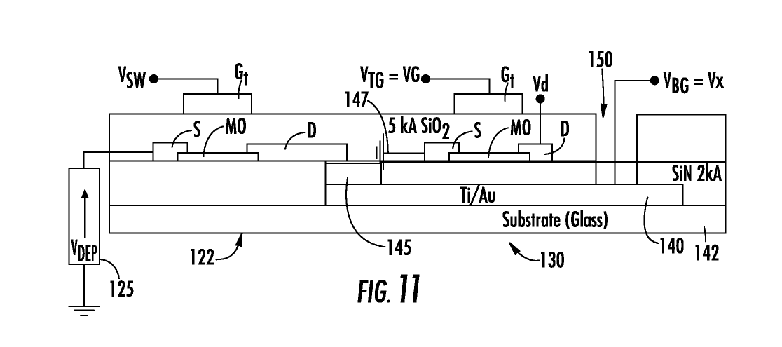

Referring now to FIGS. 9 and 10, specific individually addressable dielectrophoresis and sensing devices 100 incorporated into a sensing array 110 in accordance with the present invention are illustrated. In order to further improve the separation performance of array 110 of dielectrophoresis and sensing devices 100, the DEP electrodes may be separated and individually addressed to allow the customization of the electric field gradients. Individually addressing the DEP electrodes may also enhance the development of timing protocols which utilize pulse signals to the individual DEP electrodes on optimized sequences. In this example, DEP electrodes 120 are individually addressed by using the addition of a third MOTFT 122 which allows the DEP potential to be switched on and off single electrode 120 for each sensing device 100 so that both the DEP and sensing functions are combined.

Referring specifically to FIGS. 9 and 10, an array 110 of DEP sensing devices 100 is illustrated. Each device 100 has a separate DEP/ion sensitive electrode 120 that is not connected to other DEP/ion sensitive electrodes in array 110. In this example, a DEP signal or bias is supplied from a V_{DEP} source 125 through third MOTFT 122, when third MOTFT 122 is turned ON by a DEP select signal on the gate, to the gate of sensing MOTFT 130 (which is also connected to DEP/ion sensitive electrode 120. A row select MOTFT 132 connects one source/drain electrode of sensing MOTFT 130 to ground so that any DEP/ion signals produced by a sample on DEP/ion sensitive electrode 120 is coupled to the other source/drain electrode of sensing MOTFT 130 and appears as an output signal on a coupled data line.

This topology is especially beneficial for improving the sensitivity of the dielectrophoresis and sensing devices to collected cells and DNA, as now the separated targets (DEP solution or material) lie directly on the sensing electrode 120 instead of in close proximity as disclosed for the examples described above with all DEP electrodes connected together. The switched technology of FIGS. 9 and 10 is also uniquely enabled by the MOTFT switching transistors which have an extremely low leakage current to effectively isolate dielectrophoresis and sensing devices 100 from the DEP bias. In addition, the high mobility of the metal oxide channels (in the MOTFTs) results in a low ON resistance which effectively transfers the DEP signal to the DEP electrode when the DEP electrode needs to be biased.

Referring additionally to FIG. 11 specific construction of the MOTFTs in the specific individually addressable dielectrophoresis and sensing device of FIG. 10 is illustrated. In the specific construction, a Ti/Au DEP sensor electrode 140 is deposited on a glass substrate 142. DEP select MOTFT 122 is fabricated on substrate 142 with the drain electrode connected to DEP sensor electrode 140 at 145. V_{DEP} 125 is an AC signal source which drives the dielectrophoresis and is switched into the DEP electrode 140 by select MOTFT 122. Sensing MOTFT 130 is fabricated on DEP sensor electrode 140 with the source electrode illustrated as directly grounded at 147 (row select device is omitted to more effectively illustrate how the DEP sensing devices 100 may be configured to address the same DEP electrode 140. DEP electrode 140 is in contact with biological fluids to be sampled through an opening 150. Vx is the sensed potential induced onto the sensor electrode 140 by the sensed target. Vx can include an additional bias possibly introduced through a reference electrode to optimize the operating point of sensor MOTFT 130.

It is worth noting that for the cases used for ion sensing, the ion selective/sensitive electrode 140 is at least partially exposed to the test fluid.

Thus, the present invention describes and explains new and improved electro-chemical manipulation and charge sensing apparatus and further describes and explains new and improved electro-chemical manipulation and charge sensing apparatus coupled to a common electrode in a testing cell. The present invention describes in detail the advantages realized by incorporating MOTFT devices in the new and improved electro-chemical manipulation and charge sensing apparatus. Also, new and improved electro-chemical manipulation and charge sensing apparatus is described and explained that incorporates MOTFT devices fabricated in matrix form and, further, in an active matrix form. Further, the new and improved electro-chemical manipulation and charge sensing apparatus incorporates MOTFT devices fabricated in an active matrix form with row or individually addressable dielectrophoresis (DEP) electrodes.

Various changes and modifications to the embodiment herein chosen for purposes of illustration will readily occur to those skilled in the art. To the extent that such modifications and variations do not depart from the spirit of the invention, they are intended to be included within the scope thereof which is assessed only by a fair interpretation of the following claims.

Having fully described the invention in such clear and concise terms as to enable those skilled in the art to understand and practice the same, the invention claimed is:

1. Electro-chemical manipulation and charge sensing apparatus comprising:
a chemical/biochemical testing pad positioned on a dielectric substrate;
a sensing circuit coupled to the testing pad, the sensing circuit including at least one MOTFT device; and
a manipulation and control circuit coupled to the testing pad, the manipulation and control circuit including at least one MOTFT device.

2. Electro-chemical manipulation and charge sensing apparatus as claimed in claim 1 wherein the sensing circuit is connected directly to the chemical/biochemical testing pad by a MOTFT device and the manipulation and control circuit is connected directly to the chemical/biochemical testing pad by a MOTFT device.

3. Electro-chemical manipulation and charge sensing apparatus as claimed in claim 1 wherein the sensing circuit further comprises the gate of one MOTFT device connected to the testing pad, and the manipulation and control circuit further comprises the drain of one MOTFT device connected to the testing pad.

4. Electro-chemical manipulation and charge sensing apparatus as claimed in claim 1 wherein the chemical/biochemical testing pad includes first and second interdigitated sensing electrodes, with the first electrode being connected to the sensing circuit and the second electrode connected to the manipulation and control circuit.

5. Electro-chemical manipulation and charge sensing apparatus as claimed in claim 4 wherein the sensing circuit includes a MOTFT connected directly to the first electrode and the manipulation and control circuit includes a MOTFT connected directly to the second electrode.

6. Electro-chemical manipulation and charge sensing apparatus as claimed in claim 4 wherein one of the first electrode and second electrode is fabricated from transparent conducting material and the other of the first electrode and the second electrode is fabricated from opaque conductive material, whereby self-alignment fabrication is enhanced.

7. Electro-chemical manipulation and charge sensing apparatus as claimed in claim 1 wherein the dielectric substrate is transparent and includes one of glass or plastic.

8. Electro-chemical manipulation and charge sensing apparatus comprising:
a chemical/biochemical testing pad positioned on a dielectric substrate, the testing pad being designed for dielectrophoresis (DEP) testing and including a dielectrophoresis electrode and an ion selective/sensitive electrode positioned in charge sensing proximity to the dielectrophoresis electrode; and
a sensing MOTFT circuit positioned at least partially over a portion of the ion selective/sensitive electrode, the sensing circuit including a bottom gate MOTFT device with the gate positioned in contact with the ion selective/sensitive electrode.

9. Electro-chemical manipulation and charge sensing apparatus as claimed in claim 8 wherein the ion selective/sensitive electrode is separated from the dielectrophoresis electrode by a layer of SiNₓ.

10. Electro-chemical manipulation and charge sensing apparatus as claimed in claim 8 wherein the dielectrophoresis electrode includes one of TiPt or TiAu.

11. Electro-chemical manipulation and charge sensing apparatus as claimed in claim 8 further including a select MOTFT device, the select MOTFT device including source/drain electrodes with one of the source/drain electrodes connected to the gate of the bottom gate MOTFT device, whereby the sensing MOTFT circuit is activated when the select MOTFT device is turned ON.

12. Electro-chemical manipulation and charge sensing apparatus as claimed in claim 8 wherein the dielectric substrate is transparent and includes one of glass or plastic.

13. Electro-chemical manipulation and charge sensing apparatus as claimed in claim 8 wherein one of the dielectrophoresis electrode and the ion selective/sensitive electrode are formed in a disk shape and the other of the dielectrophoresis electrode and the ion selective/sensitive electrode are formed around the disk shape in a concentric ring.

14. Electro-chemical manipulation and charge sensing apparatus comprising:
a plurality of chemical/biochemical testing pads distributed in a matrix formation of rows and columns and positioned on a dielectric substrate, each chemical/biochemical testing pad being designed for dielectrophoresis (DEP) testing and including a dielectrophoresis electrode and an ion selective/sensitive electrode positioned in charge sensing proximity to the dielectrophoresis electrode; and
each chemical/biochemical testing pad including a sensing MOTFT circuit positioned on the ion selective/sensitive electrode.

15. Electro-chemical manipulation and charge sensing apparatus as claimed in claim 14 wherein each sensing MOTFT circuit includes a bottom gate MOTFT device with the gate positioned in contact with the ion selective/sensitive electrode

16. Electro-chemical manipulation and charge sensing apparatus as claimed in claim 15 wherein each chemical/biochemical testing pad further includes a select MOTFT device, the select MOTFT device including source/drain electrodes with one of the source/drain electrodes connected to the gate of the bottom gate MOTFT device, whereby the sensing MOTFT circuit is activated when the select MOTFT device is turned ON.

17. Electro-chemical manipulation and charge sensing apparatus as claimed in claim 16 wherein each select MOTFT device is coupled to row select circuitry, whereby a row of chemical/biochemical testing pads is selected by activation of a select MOTFT device in the selected row.

18. Electro-chemical manipulation and charge sensing apparatus as claimed in claim 14 wherein for each chemical/biochemical testing pad one of the dielectrophoresis electrode and the ion selective/sensitive electrode are formed in a disk shape and the other of the dielectrophoresis electrode and the ion selective/sensitive electrode are formed around the disk shape in a concentric ring.

19. Electro-chemical manipulation and charge sensing apparatus as claimed in claim 14 wherein each chemical/biochemical testing pad further includes a row select MOTFT device and a pad select MOTFT device.

20. Electro-chemical manipulation and charge sensing apparatus comprising:
a plurality of chemical/biochemical testing pads distributed in a matrix formation of rows and columns and positioned on a dielectric substrate, each chemical/biochemical testing pad being designed for dielectrophoresis (DEP) and ion testing and including a dielectrophoresis/ion selective electrode; and
each chemical/biochemical testing pad including a sensing MOTFT device, a row select MOTFT device, and a pad select MOTFT device, and each of the sensing MOTFT devices, the row select MOTFT devices, and the pad select MOTFT devices including source/drain electrodes and a gate electrode;
each chemical/biochemical testing pad including one of the source/drain electrodes of the row select MOTFT device connected to one of the source drain electrodes of the sensing MOTFT device and the other of the source/drain electrodes of the row select MOTFT device connected to ground or a reference voltage, one of the source/drain electrodes of the pad select MOTFT device connected to the gate of the sensing MOTFT device, whereby an individual chemical/biochemical testing pad is selected by applying a row select signal on the gate of the row select MOTFT device and a pad select signal on the gate of the pad select MOTFT device to activate the sensing MOTFT device of the selected individual chemical/biochemical testing pad.

21. Electro-chemical manipulation and charge sensing apparatus as claimed in claim 20 wherein the dielectrophoresis/ion selective/sensitive electrode of each chemical/biochemical testing pad includes a single dielectrophoresis/ion selective/sensitive electrode.

22. The electro-chemical manipulation and charge sensing apparatus as claimed in claim 21 wherein the dielectrophoresis/ion selective/sensitive electrode has a shape including one of a disc, a square, a rectangle, or a spiral.

23. Electro-chemical manipulation and charge sensing apparatus as claimed in claim 20 wherein the dielectric substrate is transparent and includes one of glass or plastic.

24. Electro-chemical manipulation and charge sensing apparatus as claimed in claim 20 wherein the dielectrophoresis/ion selective/sensitive electrode includes one of TiPt or TiAu.
